(19) United States
(12) Patent Application Publication
(10) Pub. No.: US 2005/0213779 A1
(43) Pub. Date: Sep. 29, 2005

(54) Methods and apparatus for audio signal equalization

(76) Inventor: Elon Ray Coats, Meridian, MS (US)

Correspondence Address: KAPLAN & GILMAN , L.L.P., 900 ROUTE 9 NORTH, WOODBRIDGE, NJ, 07095, US

(21) Appl. No.: 10/810,754

(22) Filed: Mar. 26, 2004

(51) Int. Cl. H03G 5/00; H04B 1/00

(52) U.S. Cl. 381/101; 381/119

(57) ABSTRACT

Methods and apparatus for adjusting a tonal quality of an audio signal include functional elements and/or steps, comprising producing a first intermediate signal containing a band of frequencies at a lower mid-range of the audio signal; producing a second intermediate signal containing a band of frequencies at an upper mid-range of the audio signal; combining the first intermediate signal, the second intermediate signal and the audio signal to produce a tonally adjusted version of the audio signal; and adjusting respective gains of the first and second intermediate signals to affect the tonal quality of the audio signal without substantially altering the tonal quality of the audio signal at frequencies between the lower mid-range and the upper mid-range.

### BACKGROUND OF THE INVENTION

The present invention relates to the adjustment of the tonal quality of an audio signal, and more particularly to the adjustment of the tonal quality of an audio signal in the mid-range frequency band.

The desirability for frequency equalization in audio electronics products has been recognized for a long time. For example, most consumer-oriented stereo receivers and amplifiers are provided with a rough equalization control, usually in the form of one or two potentiometers for adjusting treble and bass frequency settings. In more advanced applications, such as consumer or professional mixers, more versatility in the equalization adjustments may be made. For example, many mixing products include equalization controls for a low-frequency range, a mid-frequency range, and a high-frequency range. Thus, for example, a user may adjust the frequency content of an audio signal in the mid-frequency range by adjusting a control element dedicated to mid-range adjustment, such as a potentiometer.

Among the problems associated with equalization control techniques of the prior art is that it is very difficult, and sometimes impossible, to properly adjust the frequency content of mid-range audio signals. In particular, it has been discovered that pleasing audio characteristics are achieved when lower mid-range frequency content is reduced in an audio signal without reducing upper mid-range frequency content of the audio signal. It has also been discovered that pleasing audio characteristics are achieved when upper mid-range frequency content of the audio signal is boosted without adjusting the lower mid-range content of the audio signal. Still further, it has been discovered that desirable tonal characteristics are achieved when either of the lower mid-range or higher mid-range frequency content is adjusted without changing the frequency content of the audio signal between the lower and upper mid-range frequency content. Each of these characteristics will be discussed in more detail below.

The lower mid-range frequency content of an audio signal may be defined by different artisans in different ways, although it is believed that the lower mid-range frequency band for audio signals is generally between about 150 to 600 Hz. When the frequency content of a given audio signal within this band, for example about 250 Hz, exceeds a particular magnitude in comparison with other frequency content of the audio signal, an undesirable “low rumble” often manifests itself and results in annoying and/or otherwise undesirable tonal characteristics. This is particularly true when the audio signal is a voice signal. In view of this discovery, one may wish to reduce the frequency spectral energy of the audio signal in the lower mid-range band in order to reduce the low rumble.

Unfortunately, relatively unsophisticated equipment employing rough mid-range equalization control (e.g., a single potentiometer) cannot address the low rumble (in the 150 to 600 Hz range) because such control is typically operable to attenuate or boost frequencies in the 1000 Hz range. This equipment is also not able to address a concern at upper mid-range frequencies, namely vocal quality and clarity. Indeed, there is a desirability to increase the frequency spectral energy (e.g., boost the content) of the audio signal at the upper mid-range band in order to improve vocal clarity. Although skilled artisans may also differ on the definition of the upper mid-range band, it is believed that such band is between about 2750 to 6000 Hz. The relatively unsophisticated equipment employing a single potentiometer cannot address the clarity issue (in the 2750 to 6000 Hz range) because of the typical operation in the 1000 Hz range.

Still further, in many cases a more desirable solution is to address one or the other of the low rumble and vocal clarity characteristics without adjusting any other mid-range content. As the prior art technique of providing a mid-range adjustment potentiometer to adjust mid-range frequency equalization cannot address these competing concerns, more optimal solutions to audio signal equalization have not heretofore been possible.

It is noted that some audio electronics products provide even more flexibility in terms of frequency equalization. Indeed, there are numerous graphic equalizers that permit individual adjustments to a plurality of separate frequency bands (such as 31 bands), where between about 4 to 8 individual potentiometers permit adjustments in each of the lower mid-range band and the upper mid-range band. Thus, assuming that a skilled artisan were aware of the desirability to reduce low rumble and increase vocal clarity (which is not admitted as being within the prior art of the instant application), then it would be theoretically possible to deal with the competing goals of reducing frequency spectral energy in the lower mid-range band and increasing the frequency spectral energy in the upper mid-range band without necessarily doing so at the same time and without necessarily adjusting any other spectral content in the mid-range band of the audio signal.

Nevertheless, even these more flexible equalizers are still problematic because of the aforementioned issue of whether a user would actually recognize the desirability of addressing the low rumble and vocal clarity characteristics. Further, addressing the low rumble and vocal clarity problems would require significant sophistication to achieve the adjustment utilizing the separate potentiometers on the graphic equalizer equipment. For example, the operation can be complicated, non-intuitive and confusing for a novice, especially in a live sound situation where vocal quality and clarity is important and feedback is not acceptable. A typical mixing console can perform well if properly used, but it can negatively influence the sound if improperly used.

In accordance with the foregoing, there is a need in the art for methods and apparatus for adjusting the tonal quality of an audio signal in order to address the characteristics introduced by low rumble and clarity features in the mid-range spectral content of an audio signal.

### SUMMARY OF THE INVENTION

In a general sense, the present invention is directed to the adjustment of two different mid-band frequencies ranges of an audio signal, preferably using a single manual control element. These two ranges are the lower middle frequencies and the upper middle frequencies, which if misadjusted, will cause the sound to become muddy or dull. In accordance with some embodiments of the present invention, a single mid-range frequency control permits adjustment of either frequency range in such a way that the tone quality will be improved, such as by attenuating lower mid-range frequencies or boosting the upper mid-range frequencies. By having these two adjustments on one control, a sound technician will be able to quickly remove low mid-frequency rumble or add high mid-frequency clarity with little previous mixing experience. Indeed, this approach provides a simplified and consolidated method to adjust mid-range frequencies that even an inexperienced user can operate to achieve acceptable results.

In accordance with one or more aspects of the present invention, an apparatus for adjusting a tonal quality of an audio signal includes: a first audio filter operable to produce a first intermediate signal containing a band of frequencies at a lower mid-range of the audio signal; a second audio filter operable to produce a second intermediate signal containing a band of frequencies at an upper mid-range of the audio signal; a mixing circuit operable to combine the first intermediate signal, the second intermediate signal and the audio signal to produce a tonally adjusted version of the audio signal; and a user adjustable control operable to adjust respective gains of the first and second intermediate signals to affect the tonal quality of the audio signal without substantially altering the tonal quality of the audio signal at frequencies between the lower mid-range and the upper mid-range.

In accordance with one or more further aspect of the present invention, an apparatus for adjusting a tonal quality of an audio signal includes: an amplifier circuit operable to receive the audio signal and to produce a tonally adjusted version of the audio signal; a first audio filter disposed in a forward path between the audio signal and the amplifier circuit and operable to produce a feed forward signal containing a band of frequencies at a lower mid-range of the audio signal; a second audio filter disposed in a feedback path around the amplifier circuit and operable to produce a feedback signal containing a band of frequencies at an upper mid-range of the audio signal; and a user adjustable control operable to adjust respective gains of the feed forward and feedback signals to affect the tonal quality of the audio signal without substantially altering the tonal quality of the audio signal at frequencies between the lower mid-range and the upper mid-range.

In accordance with one or more further aspects of the present invention, an apparatus for adjusting a tonal quality of an audio signal includes: a first audio filter operable to produce a first intermediate signal containing a band of frequencies at a lower mid-range of the audio signal; a second audio filter operable to produce a second intermediate signal containing a band of frequencies at an upper mid-range of the audio signal; a mixing circuit operable to combine the first intermediate signal, the second intermediate signal and the audio signal to produce a tonally adjusted version of the audio signal; and a user adjustable control operable to adjust either of the respective gains of the first and second intermediate signals without adjusting the other of the respective gains of the first and second intermediate signals to affect the tonal quality of the audio signal.

In accordance with one or more further aspects of the present invention, an apparatus for adjusting a tonal quality of an audio signal includes: means for producing a first intermediate signal containing a band of frequencies at a lower mid-range of the audio signal; means for producing a second intermediate signal containing a band of frequencies at an upper mid-range of the audio signal; means for combining the first intermediate signal, the second intermediate signal and the audio signal to produce a tonally adjusted version of the audio signal; and means for adjusting respective gains of the first and second intermediate signals to affect the tonal quality of the audio signal without substantially altering the tonal quality of the audio signal at frequencies between the lower mid-range and the upper mid-range.

In accordance with one or more further aspects of the present invention, a method of adjusting a tonal quality of an audio signal includes: producing a first intermediate signal containing a band of frequencies at a lower mid-range of the audio signal; producing a second intermediate signal containing a band of frequencies at an upper mid-range of the audio signal; combining the first intermediate signal, the second intermediate signal and the audio signal to produce a tonally adjusted version of the audio signal; and adjusting respective gains of the first and second intermediate signals to affect the tonal quality of the audio signal without substantially altering the tonal quality of the audio signal at frequencies between the lower mid-range and the upper mid-range.

In accordance with one or more further aspects of the present invention, a method of adjusting a tonal quality of an audio signal includes: producing a first intermediate signal containing a band of frequencies at a lower mid-range of the audio signal; producing a second intermediate signal containing a band of frequencies at an upper mid-range of the audio signal; combining the first intermediate signal, the second intermediate signal and the audio signal to produce a tonally adjusted version of the audio signal; and adjusting either of the respective gains of the first and second intermediate signals without adjusting the other of the respective gains of the first and second intermediate signals to affect the tonal quality of the audio signal.

Other aspects, features, and advantages of the present invention will be apparent to one skilled in the art from the description herein taken in conjunction with the accompanying drawings.

### DESCRIPTION OF THE DRAWINGS

For the purposes of illustration, there are shown in the drawings forms that are presently preferred, it being understood, however, that the invention is not limited to the precise arrangements and instrumentalities shown.

FIG. 1 is a block diagram of an equalization circuit in accordance with one or more aspects of the present invention; and

FIG. 2 is a detailed schematic that is suitable for implementing the equalization circuit of FIG. 1.

### DETAILED DESCRIPTION OF THE PREFERRED EMBODIMENTS

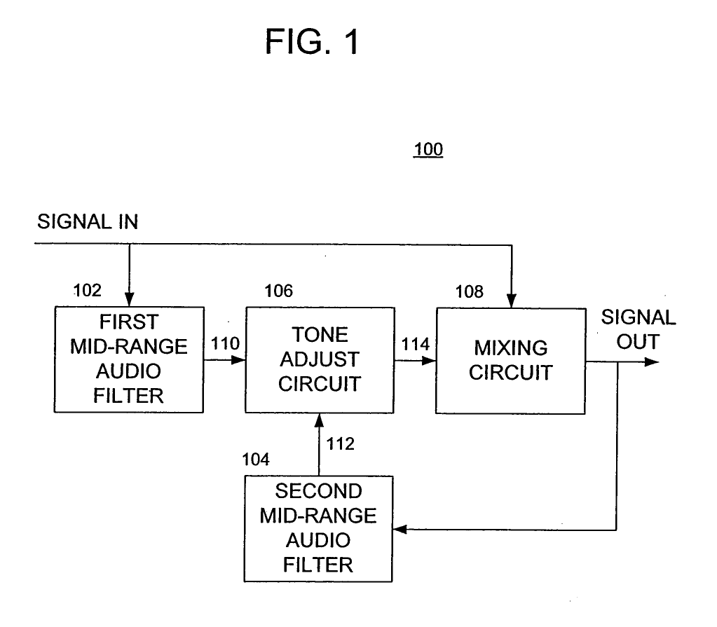

Referring now to the drawings, wherein like numerals indicate like elements, there is shown in FIG. 1 an equalization circuit 100 in accordance with one or more aspects of the present invention. The equalization circuit 100 includes a first mid-range audio filter 102, a second mid-range audio filter 104, a tone adjust circuit 106 and a mixing circuit 108. The first mid-range audio filter 102 is preferably operable to produce a first intermediate signal on line 110 containing a band of frequencies at a lower mid-range of the audio signal on a line labeled SIGNAL IN. The second mid-range audio filter 104 is preferably operable to produce a second intermediate signal on line 112 containing a band of frequencies at an upper mid-range of the audio signal. In a preferred configuration, the second mid-range audio filter 104 receives a tonally adjusted version of the audio signal on the line labeled SIGNAL OUT. It is noted, however, that in alternate configurations, the second mid-range audio filter 104 may receive the audio signal directly or indirectly from the SIGNAL IN line. These alternatives will be discussed in more detail hereinbelow.

The first intermediate signal on line 110 and the second intermediate signal on line 112 are input to the tone adjust circuit 106. An output from the tone adjust circuit on line 114 is input to the mixing circuit 108. The mixing circuit 108 is preferably operable to combine the first intermediate signal, the second intermediate signal, and the audio signal in accordance with adjustments from the tone adjust circuit 106 to produce the tonally adjusted version of the audio signal. More particularly, the tone adjust circuit 106 is preferably operable to adjust respective gains of the first and second intermediate signals on lines 110, 112 to affect the tonal quality of the audio signal.

It is preferred that the user adjustability is carried out without substantially altering the tonal quality of the audio signal at frequencies between the lower mid-range and the upper mid-range. It is also preferred that the tone adjust circuit 106 effects the adjustment in either of the respective gains of the first and second intermediate signals without adjusting the other of the respective gains of the first and second intermediate signals. In other words, it is preferred that a user may adjust the gain of the first intermediate signal on line 110 without effecting the gain of the second intermediate signal on line 112 such that the mixing circuit 108 combines the respective signals in a way that does not effect the tonal quality of the audio signal outside the lower mid-range content of the audio signal. Similarly, it is preferred that the tone adjust circuit 106 effects an adjustment in the gain of the second intermediate signal on line 112 without adjusting the gain of the first intermediate signal on line 110 such that the mixing circuit 108 combines the respective signals to adjust the tonal quality of the audio signal only within the upper mid-range content of the audio signal.

While skilled artisans may define the lower mid-range frequency content of an audio signal in different ways, it is believed that the lower mid-range band is between about 150 to 600 Hz, between about 200 to 500 Hz, and/or between about 200 to 350 Hz. In this regard, it is preferred that the first mid-range audio filter 102 is a bandpass filter having a center frequency at about 250 Hz. Skilled artisans may also differ on the definition of the upper mid-range band of an audio signal, although it is believed that such band is between about 2750 to 6000 Hz, between about 3000 to 6000 Hz, between about 3000 to 5000 Hz, and/or between about 4000 to 5000 Hz. In this regard, it is preferred that the second mid-range audio filter 104 is a bandpass filter having a center frequency at about 4000 Hz. It is noted that in alternative embodiments of the present invention, the center frequencies and/or the Q-factor of either or both of the first and second mid-range audio filters 102, 104 may be adjusted either during manufacture and/or by the user.

As illustrated in FIG. 1, the first mid-range audio filter 102 receives its input from the SIGNAL IN line, while the second mid-range audio filter 104 may receive its input from the SIGNAL OUT line of the equalization circuit 100. In this configuration, the first mid-range audio filter 102 is disposed in a forward path between the audio signal and the mixing circuit 108. Thus, the first intermediate signal may be referred to as a feed forward signal. On the other hand, the second mid-range audio filter 104 is disposed in a feedback path around the mixing circuit 108 and, therefore, the second intermediate signal on line 112 may be referred to a feedback signal. Thus, assuming that the mixing circuit 108 includes some gain, the frequency content of the tonally adjusted audio signal may include an increase in the frequency spectral energy of the second intermediate signal as a function of the adjusted gain of the second intermediate signal. This is so even if the tone adjust circuit 106 is a passive circuit. As the tonally adjusted audio signal is preferably characterized at least in part by frequency spectral energy of the audio signal being reduced by frequency spectral energy of the first intermediate signal, neither the first mid-range audio filter 102 nor the tone adjust circuit 106 need be active circuits to achieve this result.

In alternative configurations, the second mid-range audio filter 104 may receive its input more directly from the SIGNAL IN line, which may require some active gain circuitry within the second mid-range audio filter 104 and/or the tone adjust circuit 106 in order to boost the frequency spectral energy of the audio signal within the upper mid-range frequency band.

It is noted that the methods and apparatus for adjusting the tonal quality of the audio signal described thus far and/or described later in this document, may be achieved utilizing any of the known technologies, such as standard digital circuitry, analog circuitry, any of the known processors that are operable to execute software and/or firmware programs, programmable digital devices or systems, programmable array logic devices, or any combination of the above.

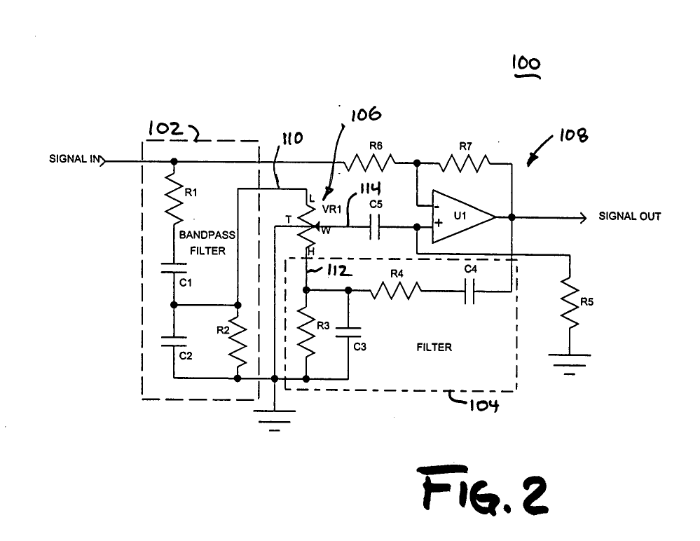

Among the suitable implementations of the equalizer circuit 100 of FIG. 1 is the analog hardware implementation 100 illustrated in FIG. 2. As shown, the first mid-range audio filter 102 is implemented utilizing a passive bandpass filter. It is noted, however, that any of the known or hereinafter developed bandpass filter implementations may be employed, such as active filters, adjustable filters, digital filters, programmable filters, etc. Similarly, the second mid-range audio filter 104 is shown in FIG. 2 as being implemented utilizing a passive bandpass filter configuration. As with the first audio filter 102, the second audio filter 104 may be implemented in any number of ways.

The tone adjust circuit 106 is implemented utilizing a single potentiometer VR1. The user is preferably permitted to adjust the potentiometer VR1 in order to achieve the tonal adjustment of the audio signal. In particular, the potentiometer VR1 is preferably operable to sweep from a first extreme position associated with a first input terminal L to a second extreme position associated with a second input terminal H through variable intermediate positions associated with an output terminal (or wiper) W. The first intermediate signal on line 110 is preferably coupled to the first input terminal L of the potentiometer VR1. The second intermediate signal on line 112 is preferably coupled to the second input terminal H of the potentiometer VR1. The output of the tone adjust circuit 106, i.e., the signal of the wiper W is input to the mixing circuit 108. User actuation of the wiper W of the potentiometer VR1 effects adjustment of the respective gains of the first and second intermediate signals.

It is noted that the potentiometer VR1 also includes a fixed intermediate position associated with a third input terminal T is coupled to a null position, namely ground. As the fixed intermediate position of the potentiometer VR1 and the mixing circuit 108 are referenced to the same potential, e.g., ground, the variable intermediate positions of the potentiometer VR1 between the fixed intermediate position T and the first extreme position permits adjustment of the first intermediate signal without permitting adjustment of the second intermediate signal. Similarly, variable intermediate positions between the fixed intermediate position T and the second extreme position permits adjustment of the second intermediate signal without permitting adjustment of the first intermediate signal.

The mixing circuit 108 is illustrated as being implemented utilizing an operational amplifier U1, where the audio signal is coupled to an inverting terminal thereof and the output of the tone adjust circuit 106 is coupled to a non-inverting terminal thereof. In this configuration, the tonally adjusted audio signal on line SIGNAL OUT is characterized at least in part by frequency spectral energy of the audio signal being reduced by frequency spectral energy of the first intermediate signal as a function of the adjusted gain thereof. Further, the tonally adjusted audio signal is characterized at least in part by frequency spectral energy of the audio signal being increased by frequency spectral energy of the second intermediate signal as a function of the adjusted gain thereof.

Advantageously, the methods and apparatus of the present invention permit desirable characteristics in an audio signal, such as reducing lower mid-range frequency content in the audio signal without reducing other mid-range frequency content. Further, the present invention permits boosting upper mid-range frequency content of the audio signal without changing other mid-range frequency content. Still further, the present invention permits adjusting either the lower mid-range frequency content or the upper mid-range frequency content of an audio signal independently without adjustment of the one affecting the adjustment of the other.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. An apparatus for adjusting a tonal quality of an audio signal, comprising:
a first audio filter operable to produce a first intermediate signal containing a band of frequencies at a lower mid-range of the audio signal;
a second audio filter operable to produce a second intermediate signal containing a band of frequencies at an upper mid-range of the audio signal;
a mixing circuit operable to combine the first intermediate signal, the second intermediate signal and the audio signal to produce a tonally adjusted version of the audio signal; and
a user adjustable control operable to adjust respective gains of the first and second intermediate signals to affect the tonal quality of the audio signal without substantially altering the tonal quality of the audio signal at frequencies between the lower mid-range and the upper mid-range.

2. The apparatus of claim 1, wherein the user adjustable control is a single potentiometer operable to sweep from a first extreme position to a second extreme position in order to adjust the respective gains of the first and second intermediate signals.

3. The apparatus of claim 2, wherein the adjustment of the single potentiometer effects an adjustment in either of the respective gains of the first and second intermediate signals without adjusting the other of the respective gains of the first and second intermediate signals.

4. The apparatus of claim 1, wherein at least one of the mixing circuit and the user adjustable control is operable to adjust either of the respective gains of the first and second intermediate signals without adjusting the other of the respective gains of the first and second intermediate signals.

5. The apparatus of claim 1, wherein at least one of:
the tonally adjusted audio signal is characterized at least in part by frequency spectral energy of the audio signal being reduced by frequency spectral energy of the first intermediate signal as a function of the adjusted gain of the first intermediate signal; and
the tonally adjusted audio signal is characterized at least in part by frequency spectral energy of the audio signal being increased by frequency spectral energy of the second intermediate signal as a function of the adjusted gain of the second intermediate signal.

6. The apparatus of claim 1, wherein the lower mid-range band of frequencies is one of: (i) between about 150 to 600 Hz; (ii) between about 200 to 500 Hz; (iii) between about 200 to 350 Hz; and (iv) about 250 Hz.

7. The apparatus of claim 1, wherein the upper mid-range band of frequencies is one of: (i) between about 2750 to 6000 Hz; (ii) between about 3000 to 6000 Hz; (iii) between about 3000 to 5000 Hz; (iv) between about 4000 to 5000 Hz; and (v) about 4000 Hz.

8. An apparatus for adjusting a tonal quality of an audio signal, comprising:
an amplifier circuit operable to receive the audio signal and to produce a tonally adjusted version of the audio signal;
a first audio filter disposed in a forward path between the audio signal and the amplifier circuit and operable to produce a feed forward signal containing a band of frequencies at a lower mid-range of the audio signal;
a second audio filter disposed in a feedback path around the amplifier circuit and operable to produce a feedback signal containing a band of frequencies at an upper mid-range of the audio signal; and
a user adjustable control operable to adjust respective gains of the feed forward and feedback signals to affect the tonal quality of the audio signal without substantially altering the tonal quality of the audio signal at frequencies between the lower mid-range and the upper mid-range.

9. The apparatus of claim 8, wherein:
the user adjustable control is a single potentiometer operable to sweep from a first extreme position associated with a first input terminal to a second extreme position associated with a second input terminal through a variable intermediate position associated with an output terminal;
the feed forward signal is coupled to the first input terminal of the potentiometer, the feedback signal is coupled to the second input terminal of the potentiometer, and the output terminal of the potentiometer is coupled to an input of the amplifier circuit; and
user actuation of the potentiometer effects adjustment of the respective gains of the feed forward and feedback signals in order to affect the tonal quality of the audio signal.

10. The apparatus of claim 9, wherein the single potentiometer is operable to effect adjustments in either of the respective gains of the first and second intermediate signals without adjusting the other of the respective gains of the first and second intermediate signals.

11. The apparatus of claim 10, wherein the single potentiometer includes a fixed intermediate position associated with a third input terminal and the third input terminal is coupled to a null potential such that: (i) variable intermediate positions between the fixed intermediate position and the first extreme position permits adjustment of the first intermediate signal without permitting adjustment of the second intermediate signal; and (ii) variable intermediate positions between the fixed intermediate position and the second extreme position permits adjustment of the second intermediate signal without permitting adjustment of the first intermediate signal.

12. The apparatus of claim 8, wherein at least one of:
the first audio filter is a bandpass filter having a center frequency one of: (i) between about 150 to 600 Hz; (ii) between about 200 to 500 Hz; (iii) between about 200 to 350 Hz; and (iv) about 250 Hz; and
the second audio filter is a bandpass filter having a center frequency one of: (i) between about 2750 to 6000 Hz; (ii) between about 3000 to 6000 Hz; (iii) between about 3000 to 5000 Hz; (iv) between about 4000 to 5000 Hz; and (v) about 4000 Hz.

13. An apparatus for adjusting a tonal quality of an audio signal, comprising:
a first audio filter operable to produce a first intermediate signal containing a band of frequencies at a lower mid-range of the audio signal;
a second audio filter operable to produce a second intermediate signal containing a band of frequencies at an upper mid-range of the audio signal;
a mixing circuit operable to combine the first intermediate signal, the second intermediate signal and the audio signal to produce a tonally adjusted version of the audio signal; and
a user adjustable control operable to adjust either of the respective gains of the first and second intermediate signals without adjusting the other of the respective gains of the first and second intermediate signals to affect the tonal quality of the audio signal.

14. An apparatus for adjusting a tonal quality of an audio signal, comprising:
means for producing a first intermediate signal containing a band of frequencies at a lower mid-range of the audio signal;
means for producing a second intermediate signal containing a band of frequencies at an upper mid-range of the audio signal;
means for combining the first intermediate signal, the second intermediate signal and the audio signal to produce a tonally adjusted version of the audio signal; and
means for adjusting respective gains of the first and second intermediate signals to affect the tonal quality of the audio signal without substantially altering the tonal quality of the audio signal at frequencies between the lower mid-range and the upper mid-range.

15. A method of adjusting a tonal quality of an audio signal, comprising:
producing a first intermediate signal containing a band of frequencies at a lower mid-range of the audio signal;
producing a second intermediate signal containing a band of frequencies at an upper mid-range of the audio signal;
combining the first intermediate signal, the second intermediate signal and the audio signal to produce a tonally adjusted version of the audio signal; and
adjusting respective gains of the first and second intermediate signals to affect the tonal quality of the audio signal without substantially altering the tonal quality of the audio signal at frequencies between the lower mid-range and the upper mid-range.

16. The method of claim 15, further comprising: adjusting either of the respective gains of the first and second intermediate signals without adjusting the other of the respective gains of the first and second intermediate signals.

17. The method of claim 15, wherein at least one of:
the tonally adjusted audio signal is characterized at least in part by frequency spectral energy of the audio signal being reduced by frequency spectral energy of the first intermediate signal as a function of the adjusted gain of the first intermediate signal; and
the tonally adjusted audio signal is characterized at least in part by frequency spectral energy of the audio signal being increased by frequency spectral energy of the second intermediate signal as a function of the adjusted gain of the second intermediate signal.

18. The method of claim 15, wherein the lower mid-range band of frequencies is one of: (i) between about 150 to 600 Hz; (ii) between about 200 to 500 Hz; (iii) between about 200 to 350 Hz; and (iv) about 250 Hz.

19. The method of claim 15, wherein the upper mid-range band of frequencies is one of: (i) between about 2750 to 6000 Hz; (ii) between about 3000 to 6000 Hz; (iii) between about 3000 to 5000 Hz; (iv) between about 4000 to 5000 Hz; and (v) about 4000 Hz.

20. The method of claim 15, further comprising providing a single potentiometer to permit user adjustment of the respective gains of the first and second intermediate signals.

21. A method of adjusting a tonal quality of an audio signal, comprising:
producing a first intermediate signal containing a band of frequencies at a lower mid-range of the audio signal;
producing a second intermediate signal containing a band of frequencies at an upper mid-range of the audio signal;
combining the first intermediate signal, the second intermediate signal and the audio signal to produce a tonally adjusted version of the audio signal; and
adjusting either of the respective gains of the first and second intermediate signals without adjusting the other of the respective gains of the first and second intermediate signals to affect the tonal quality of the audio signal.
